(19) United States
(12) Patent Application Publication
(10) Pub. No.: US 2008/0025204 A1
(43) Pub. Date: Jan. 31, 2008

(54) Method to utilize physical layer channel state information to improve video quality

(75) Inventors: Hayder Radha, East Lansing, MI (US); Shirish S. Karande, Lansing, MI (US); Utpal Parrikar, San Diego, CA (US); Kiran Misra, Lansing, MI (US)

Correspondence Address: HARNESS, DICKEY & PIERCE, P.L.C., P.O. BOX 828, BLOOMFIELD HILLS, MI, 48303, US

(73) Assignee: Board of Trustees of Michigan State University, East Lansing, MI (US)

(21) Appl. No.: 11/725,242

(22) Filed: Mar. 16, 2007

Related U.S. Application Data
(60) Provisional application No. 60/784,108, filed on Mar. 17, 2006.

(51) Int. Cl. G01R 31/08

(52) U.S. Cl. 370/216

(57) ABSTRACT

A method is provided for improving error recovery of corrupt data packets in a wireless communication system. The method includes: receiving a plurality of incoming data packets over a wireless medium at a receiver; capturing an indicator of bit errors for each of the data packets at a layer of the receiver below an application layer; passing the bit error indicator for each of the data packets to the application layer of the receiver; and performing an error recovery operation in relation to a given data packet at the application layer using the bit error indicator associated with the given data packet.

### CROSS-REFERENCE TO RELATED APPLICATIONS

This application claims the benefit of U.S. Provisional Application No. 60/784,108, filed on Mar. 17, 2006. The disclosure of the above application is incorporated herein by reference.

### FIELD

The present disclosure relates generally to a method for improving error recovery of corrupt data packets in a wireless communication system.

### BACKGROUND

Many recent research efforts have focused on the utility (especially for multimedia transmission) of cross-layer protocols that recover information from corrupted packets. The pivotal concept behind these works is to avoid completely dropping the content of a partially corrupted packet. The responsibility of recovering information from the corrupted packet can be given to the link-level or the application level. This disclosure contemplates a system model in which the responsibility of error recovery is given to the application level forward error correction (FEC) scheme.

In traditional packet based communication, a packet is either erased or is completely error free. Thus the receiver has complete channel state information (CSI). In contrast, when corrupted packets are relayed to the application layer of a receiver in a wireless communication system, the received packets at the application level are not necessarily error free. Information about the corruption level or the bit error rate in a packet can help in enhancing the error recovery performance. For instance, using channel state information to meagerly identify uncorrupted packets from corrupted ones is sufficient to provide substantial performance gains in terms of the eventual video quality. However, none of the previous work has analyzed either theoretically or experimentally, the utility of channel state information that could provide a robust estimate of the bit error rate in a corrupted packet, on a per-packet basis. A primary reason for this could be the inability to identify methodologies in existing network hardware/software implementations that could provide such channel state information without any additional cost/modifications.

More recently, radio hardware used for reception of 802.11b frames is capable of recording and associating a Signal to Silence Ratio (SSR) to each received frame. It has been shown that the relationship of the SSR indication to the bit error rate in the corrupted packet does not vary significantly across different environments. Therefore, the SSR indication associated with each packet can be used to provide robust channel state information to the cross-layer error recovery mechanism. As a basis for this disclosure, experiments were conducted with actual 802.11b residue error traces to establish the utility of the SSR indications in cross-layer systems. Video applications are typically extremely bandwidth hungry and hence have served as the prime stimulus for design of the considered cross-layer schemes.

The statements in this section merely provide background information related to the present disclosure and may not constitute prior art.

### SUMMARY

A method is provided for improving error recovery of corrupt data packets in a wireless communication system. The method includes: receiving a plurality of incoming data packets over a wireless medium at a receiver; capturing an indicator of bit errors for each of the data packets at a layer of the receiver below an application layer; passing the bit error indicator for each of the data packets to the application layer of the receiver; and performing an error recovery operation in relation to a given data packet at the application layer using the bit error indicator associated with the given data packet.

Further areas of applicability will become apparent from the description provided herein. It should be understood that the description and specific examples are intended for purposes of illustration only and are not intended to limit the scope of the present disclosure.

### DRAWINGS

FIG. 1 is a diagram illustrating an exemplary network model;

FIG. 2 is a flowchart depicting an exemplary cross-layer methodology;

FIGS. 3A and 4A are diagrams of a temporal snapshot for trace four and one, respectively; and

FIGS. 3B and 3C are video frames captured for trace four where channel state information is and is not employed, respectively;

FIGS. 4B and 4C are video frames captured for trace four where channel state information is and is not employed, respectively.

The drawings described herein are for illustration purposes only and are not intended to limit the scope of the present disclosure in any way.

### DETAILED DESCRIPTION

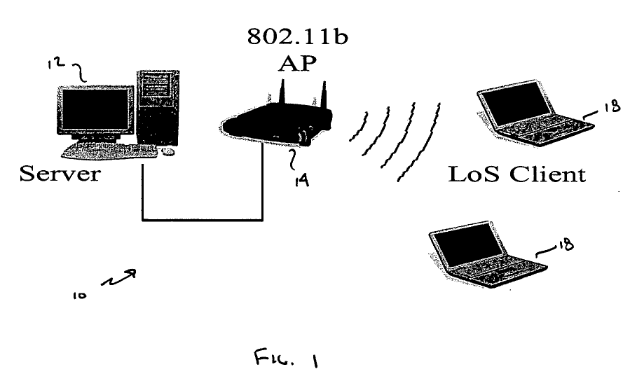

FIG. 1 illustrates an exemplary network model 10 considered by this disclosure. A video server 12 is responsible for forward error correction (FEC) encoding of the video data. The encoded data packets are in turn passed along to an access point 14 which serves as a gateway to a local area network 16. The access point 14 is capable of multicasting the encoded data packets over a wireless network to multiple clients 18. Clients receiving the encoded data packets employ a cross-layer methodology as further described below. Since a cross-layer methodology can be completely receiver driven, it is feasible for clients that do not employ a cross-layer strategy to co-exist with the ones that do receive these packets. Further areas of applicability will become apparent from the description provided herein. It should be understood that the description and specific examples are intended for purposes of illustration only and are not intended to limit the scope of the present disclosure.

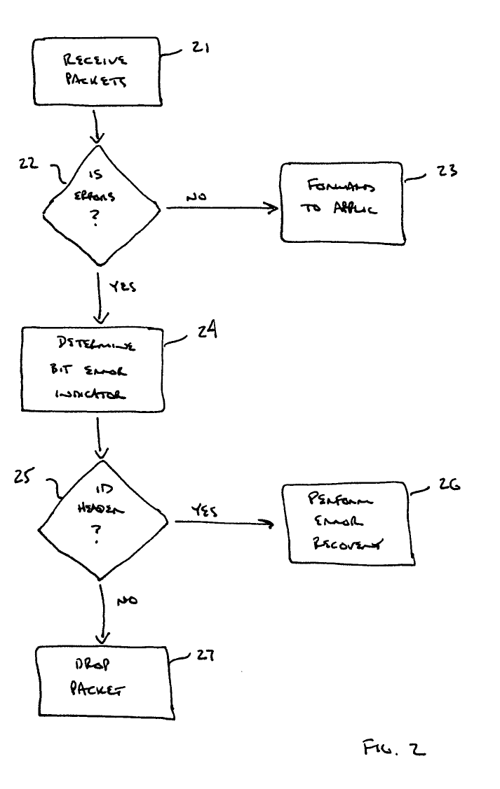

An exemplary cross-layer methodology is further described in relation to FIG. 2. Incoming data packets are received at 21 over a wireless medium at a receiver. First, each incoming data packet is evaluated at 22 to determine whether it contains errors. Incoming data packets are evaluated at a layer of the receiver below an application layer as defined by an Open System Interconnection (OSI) model. In an exemplary embodiment, the 802.11 MAC Frame Check Sequence (FCS) function residing in the data link layer can detect whether a received packet is error free. Other error checking mechanisms are contemplated by this disclosure.

Data packets without any errors are sent on as indicated at 23 to the application layer of the receiver for further processing. When a data packet is deemed to contain bit errors, the packet is further assessed at 25 to determine if the errors are found in the header of the data packet, thereby obscuring the identity of the data packet. If a corrupted packet can be adequately identified from the header information, the packet may be forwarded on to the application layer further processing. If the corrupted packet cannot be adequately identified, then the data packet is dropped as indicated at 27.

For each corrupted data packet sent to the application layer, an indicator of the bit errors associated with that data packet is also passed to the application layer. Likewise, the indicator of the bit errors is captured or determined at a layer of the receiver below the application layer. In an exemplary embodiment, the bit error indicator for the packet may be reported by the communication protocol operating at the data link layer of the receiver. For example, the bit error indicator may be a signal to silence ratio (SSR) value as provided in accordance with 802.11b WLAN. It is readily understood that other types of indicators for the bit errors contained in a given data packet are contemplated by this disclosure. Furthermore, it is contemplated the bit error indicator may be captured at a physical layer of the receiver or at some other layer below the application layer as defined by the Open System Interconnection (OSI) model.

At the application layer, corrupt data packets undergo an error recovery operation which uses the bit error indicator associated with the corrupt data packet. In an exemplary embodiment, the bits of the corrupt data packet are decoded using a low density parity check (LDPC) decoding scheme in a manner further described below. It is envisioned that bit error indictor may be used in other types of decoding schemes or forward error correction schemes.

An exemplary forward error correction block may be broken down into different codewords that were interleaved across data packets. Each data packet contributes 64 bits to a codeword. Thus, for given a packet size of 1024 bytes, the total codewords in a single FEC block were 128. In the case of LDPC decoding, a codeword consisted of k=8192 bits and therefore each FEC packet block consisted of 64 message packets. The number of parity packets are increased in steps of 4 packets and the number of parity bits in each codeword are increased in steps of 512 bits, so as to provide FEC blocks with packet-block-length varying from 68 packets to 128 packets. Thus we studied the performance of codes from rate 0.94 to rate 0.5. For purposes of brevity, results are reported only for the maximal rates for which the eventual probability of decoding failure for the LDPC decoding was under ˜15%. The Progressive-Edge-Growth (PEG) algorithm based on large-girth tanner graphs was used to determine check matrices for all the LDPC codes.

A numerically efficient version of the LDPC decoding algorithm uses the log-likelihood ratios (LLR) to estimate the transmitted codeword. In the LDPC decoding algorithm, the LLR L(cᵢ) associated with code bit cᵢ is initialized at the start of the decoding on the basis of the received bit yᵢ and an apriori assumption of the bit error probability of the i^{th} bit being Pₑ as

$$L ( {c}_{i} ) = {( - 1 )}^{{y}_{i}} log ( \frac{1 - {P}_{e}}{{P}_{e}} ) \qquad ( 1 )$$

The message-passing algorithm (log-domain sum-product algorithm) is then iteratively used to update L(cᵢ). In a LDPC decoding algorithm, or more generically in an iterative channel decoding algorithm, the likelihood of each bit is updated as
L(cᵢ)^{(l)}=f(L(cᵢ)^{(l-1)},L(cᵢ))=f(L(cᵢ)^{(l-1)},L(cᵢ)⁽⁰⁾)
where l is the iteration. A bit is decoded to 1 if L(cᵢ)≦0 and 0 if L(cᵢ)>0. It is envisioned that this technique may be extended to non-binary bit values which may be received from certain demodulating schemes. Moreover, it is understood that this is merely an exemplary technique for decoding bits and other techniques fall within the broader aspects of this disclosure.

An accurate initialization of LLR plays a key role in the performance of LDPC codes and thus improved channel state information can help in improving the LDPC decoding. If a packet is received without any errors, then L(cᵢ) corresponding to the bits in that packet is obtained by setting Pₑ=0; and similarly if a packet is dropped, L(cᵢ) is obtained by setting Pₑ=0.5. With extensive experimentation with 802.11b wireless traces, an empirical relationship between the bit error probability in a corrupted packet and the associated SSR indication has been established. In an SSR_aware scheme, this empirical relationship is used to obtain Pₑ=ε(SSR) for each data packet. In other words, the bit error probability for the data packet is derived from the bit error indicator passed to the application layer. For comparison, in a SSR_unaware scheme, Pₑ= ε̅(̅t̅r̅a̅c̅e̅)̅, where ε̅(̅t̅r̅a̅c̅e̅)̅ represents the average probability of bit error in a corrupted packet for a given residue error trace.

Additional methods for choosing Pₑ are also contemplated. Pₑ may be generalized as follows:
Pₑ_{ₓ}=f( . . . ,ε(SSRₓ₊₁),ε(SSRₓ₊₂),ε(SSRₓ),ε(SSRₓ₋₁),ε(SSRₓ₋₂), . . . )
In accordance with this generalization, Pₑ may be determined by:

$${P}_{{e}_{x}} = \frac{1}{2 m + 1} {\sum }_{j = - m}^{j = m} ɛ ( S S {R}_{x + j} )$$

or more generically,

$${P}_{{e}_{x}} = {\sum }_{j = - m}^{j = m} {w}_{j} ɛ ( S S {R}_{x + j} ) s . t . ( {\sum }_{j = - m}^{j = m} {w}_{j} ) = 1$$

Thus, Pₑ for a packet depends on the SSR indications of neighboring packets. In another example, Pₑ=f(ε( . . . ,SSRᵢ₊₂,SSR_{i 30 1},SSRᵢ,SSRᵢ₋₁,SSRᵢ₋₂, . . . )), such that

$${P}_{{e}_{x}} = {\sum }_{j = - m}^{j = m} {w}_{j} ɛ ( S S {R}_{x + j} ) s . t . ( {\sum }_{i = - m}^{j = m} {w}_{i} ) = 1$$

Other methods for choosing Pₑ are also contemplated by this disclosure.

Thus far, it was assumed that Pₑ is set identically for all the bits in a packet. However, the usage can be generalized as:

$${L ( {c}_{ix} )}^{( 0 )} = {w}_{i} \cdot {( - 1 )}^{{y}_{ix}} log ( \frac{1 - {P}_{{e}_{ix}}}{{P}_{{e}_{ix}}} )$$

where, i denotes the ith bit in a packet, x denotes the xth packet, wᵢ is just bit-location dependent weighting coefficient and Pₑ_{ᵢₓ} is now a bit location dependent function of SSR. For example, Pₑ may be determined as follows:

$${P}_{{e}_{ix}} = \frac{1}{2 ⌊ \frac{i}{S} ⌋ + 1} {\sum }_{j = - ⌊ \frac{i}{S} ⌋}^{j = ⌊ \frac{i}{S} ⌋} ɛ ( S S {R}_{j + x} ) ,$$

where S is some integer, and

$$⌊ \frac{i}{S} ⌋$$

is the greatest integer smaller than i/S. Remember index i refers to different bit locations within the packet, while index x refers to different packets. Thus, you can understand the above expression as follows. For, the first 99 bits in the packet set: Pₑ=ε(SSRₓ). For the next 100 bits, set it as

$${P}_{{e}_{i x}} = \frac{1}{3} ( ɛ ( S S {R}_{x - 1} ) + ɛ ( S S {R}_{x} ) + ɛ ( S S {R}_{x + 1} ) )$$

so on and so forth.

An additional method for using SSR to modify the operation of LDPC is as follows:
L(c_{i,x})^{(l)}=f(\tilde{L}(c_{i,x})^{(l-1)},L(c_{i,x}))
where
\tilde{L}(c_{i,x})^{(l)}=f(L(c_{i-b(SSR),x})^{(l)}, . . . ,L(c_{i-1,x})^{(l)},L(c_{i,x})^{(l)},L(c_{i+1,x})^{(l)}, . . . ,L(c_{i-b(SSR),x}),L(c_{i,x)})
This equation basically states that after each iteration of LDPC decoding, we shall look at the current belief of the neighboring nodes to update our belief in the value of each bit. Thus, the size of the neighborhood can be determined by SSR.

In another example, a statistical model may be used to predict whether a given data bit in a stream of data bits is in error. The statistical model is defined as a Markov model where the states of the model correlate to a bit error pattern of data bits which precede the given data bit. The statistical model may be adapted using the bit error indicator, thereby deriving a bit error probability for the corrupt data packet. Further information regarding this exemplary technique may be found in U.S. Patent Application No. ______ entitled “Modeling of Residue Errors using Models that Adapt on the Basis of Link Quality Indicators” which is filed concurrently herewith and incorporated herein by reference. Other techniques for deriving Pₑ from the SSR indicator are contemplated by this disclosure.

Experiments with actual 802.11b error traces show that channel state information provided by SSR indications can be used to improve error recovery performance of an FEC scheme in the manner described above. Prior to presenting experimental results, it is important to develop some theoretical deductions and insight in the considered problem. For this purpose, consider the following notation. For a packet received with a particular SSR indication, let (i) δ(SSR) represent the probability of a packet being corrupted and (ii) ε(SSR) represent the probability of a bit error in the corrupted packet. Let ƒ(SSR) denote the probability of receiving a packet with a particular SSR indication. Let Z be an indicator variable that indicates whether a packet is corrupted (i.e. Z corresponds to a checksum on the data payload) and SSR is a variable that indicates the Signal to Silence Ratio. For an SSR_unaware scheme, Z is made available as side-information to the receiver, while for an SSR_aware scheme, both Z and SSR are available as side-information. Now let's assume a simplistic theoretical model, where we do not have any packet drops due to header corruption, the packet corruption process is memory-less and the bit-error process in a corrupted packet is also memory-less. For such a model, the application layer channel capacity of the SSR_unaware scheme and the SSR_aware scheme are given by equations (1) and (2) below (proofs have been omitted for purposes of brevity)
C_{SSR}_{_{—}}_{unaware}=(1−δ)+δ(1−h_{b}(ε)) (1)

$${C}_{SSR\_aware} = ( 1 - δ ) + {\sum }_{SSR} f ( S S R ) \cdot δ ( S S R ) ( 1 - {h}_{b} ( ɛ ( S S R ) ) ) \qquad ( 2 )$$

where

$$δ = {\sum }_{ssr} f ( S S R ) δ ( S S R ) \& ɛ = {\sum }_{ssr} f ( S S R ) δ ( S S R ) ɛ ( S S R )$$

represent the overall probability of a packet being corrupted and the overall probability of bit error in a corrupted packet.

Using Jensen's Inequality/Convexity, it can be easily shown that C_{SSR}_{_{—}}_{aware}≧C_{SSR}_{_{—}}_{unaware}. Thus, the SSR_aware scheme should always perform better. However an SSR_aware scheme provides negligible improvement in capacity if (i) δ is very small, which is indeed the case for “Good” SSR values, or (ii) ε(SSR) is close to 0.5 which is indeed the case for “Bad” SSR values, or (iii) ƒ(SSR)·δ(SSR) is such that most of the corrupted packets have the identical SSR indication.

Experimental error traces were categorized into “Home” and “Office” traces to represent a low interference and relatively high interference environment, respectively. It was observed that the probability of packet corruption is negligible for SSR>14 dB (i.e., “Good Range”) and the bit error rate for SSR<8 dB is very high (i.e., “Bad Range”). Thus the utility of cross-layer protocol is primarily exhibited when a significant proportion of the packets are received with SSR values in the “Transition Range” (8-14 dB). Consequently, this analysis focuses on residue error traces that were collected in channel conditions where at least 20% of the packets were received with SSR indication in the transition range. Hence, six traces were chosen (3 from each environment) of 40,000 packets each. However it should be mentioned that for the traces used in this document, the 802.11b PHY data rate was always maintained at 11 Mbps and the packet transmission rate was adjusted so as to facilitate a payload bit-rate of approximately 3 Mbps in the “Home Data” and maximum possible bit rate lesser than 11 Mbps achieved on the basis of flooding in the “Office Data”. The packet payload size was maintained at 1024 bytes.

For the purpose of video simulations, data streams were compressed using H.264. To emulate the conditions where the wireless traces were collected we use a video stream with a bit-rate of 2.1 Mbps for the simulations on Home Data, and bit-rate of 5.4 Mbps for simulations on Office Data. The source-coding rate used here is chosen meagerly to represent the total amount of video content we would expect in a typical application that is using 3 Mbps or the maximum possible bandwidth. Naturally, in actual office application a source-coding rate of 5.4 Mbps for “CIF” resolution may be too high. However, multiple video sequences can indeed provide a combined content of 5.4 Mbps. A single video sequence of 5.4 Mbps could be considered to be an approximation for such total video content. Such approximations allow us to focus on issues more core to the focus of the proposed work.

Test results are reported for test sequences “mobile” and “stefan”. The resolution of these sequences was “CIF”. We use a GOP (IBPBP . . . ) size of 15 frames, and a frame rate of 30 fps. Test sequences are repeated to provide a playout sequence of 900 picture frames. The compressed stream was mapped to the FEC scheme by embedding a video slice/video packet in each codeword. LDPC codes can detect a decoding failure, thus if any codeword could not correct all the errors we drop that slice. All standard error concealment features were turned on. In the event of data/frame loss, the previous correctly received frame was copied and also used as a reference for the motion vectors.

Experiments were conducted on actual 802.11b wireless traces. In these traces, neither the packet corruption process nor the bit error process is observed to be memory-less. However, the above theoretical insight is still helpful in understanding the result of our experimentation tabulated in Table I below.

| | | TRACE NUMBER | | | | | |
|---|---|---|---|---|---|---|---|
| | | 1 | 2 | 3 | 4 | 5 | 6 |
| ENVIRONMENT | | HOME | HOME | HOME | OFFICE | OFFICE | OFFICE |
| SSR STANDARD | | 3.2 | 3.1 | 7.7 | 3.8 | 4.1 | 7 |
| DEVIATION (in dB) | | | | | | | |
| COMPRESSED | | 2.1 | 2.1 | 2.1 | 5.4 | 5.4 | 5.4 |
| SOURCE BITRATE | | Mbps | Mbps | Mbps | Mbps | Mbps | Mbps |
| CHANNEL | | 0.8 | 0.66 | 0.94 | 0.8 | 0.66 | 0.5 |
| CODING RATE | | | | | | | |
| % | GOOD SSR | — | 3.6 | 5.4 | 0 | 0 | 3.8 |
| CODE | REGION | — | 5 | 7 | 0 | 0 | 6 |
| FAIL- | BAD SSR | 0.5 | 4 | 14 | 7 | 1.9 | — |
| URES | REGION | 2.5 | 7.8 | 16 | 18 | 3.1 | — |
| | TRANSITION | — | — | — | 100 | 100 | — |
| | SSR REGION | — | — | — | 100 | 100 | — |
| | TOTAL | 0.5 | 3.9 | 11 | 6 | 1.7 | 3.8 |
| | | 2.5 | 7.5 | 13 | 16 | 2.8 | 6.0 |
| PSNR | STEFAN | 5.5 | 0.93 | 1.19 | 1.6 | 0.78 | 0.82 |
| GAIN | MOBILE | 6.78 | 0.75 | 0 | 2.3 | 2.07 | 1.37 |
| (in | | | | | | | |
| dB) | | | | | | | |

In Table I, similar to our deductions (i) and (ii), it can be observed that it is feasible in the Good and Bad SSR ranges for the SSR_aware scheme to provide negligible benefits in the error recovery performance. Nevertheless, in the transition region, the SSR_aware scheme consistently provides an improved error recovery performance. The % code failures are reduced by a minimum of 1.2% to a maximum of 11%. It is also important to note, that though it cannot be guaranteed that an SSR_aware scheme will be helpful in the Good Range, there do exist many instances when it does help. Similarly, if the channel coding rate is reduced significantly (less than 0.33), then some performance benefit can be observed in the Bad Range too.

An extremely essential observation to make is the SSR standard deviation (std. dev.) for the corrupted packets in each trace. The standard deviation was found to be at least 3 dB in all the traces presented here. In extensive experimentation with 802.11b over millions of packets, it was observed that SSR deviation is always significant. This deviation can be observed to increase due to presence of walls or mobility. In the light of deduction (iii) the above stated observation is crucial to emphasize the practical utility of SSR indications. Furthermore, it should be stated that even when the SSR value averaged over a large number of (100 to 1000) packets is constant; the SSR indication on per packet basis can vary significantly. In such an event an SSR_aware scheme will provide performance benefits. The significance of the SSR standard deviation can be especially appreciated by observing the error recovery performance for trace 6. In trace 6 though the average channel conditions are such that the SSR values are “Good”, the variation in SSR value is significant enough for an SSR_aware scheme to exhibit improved error recovery performance.

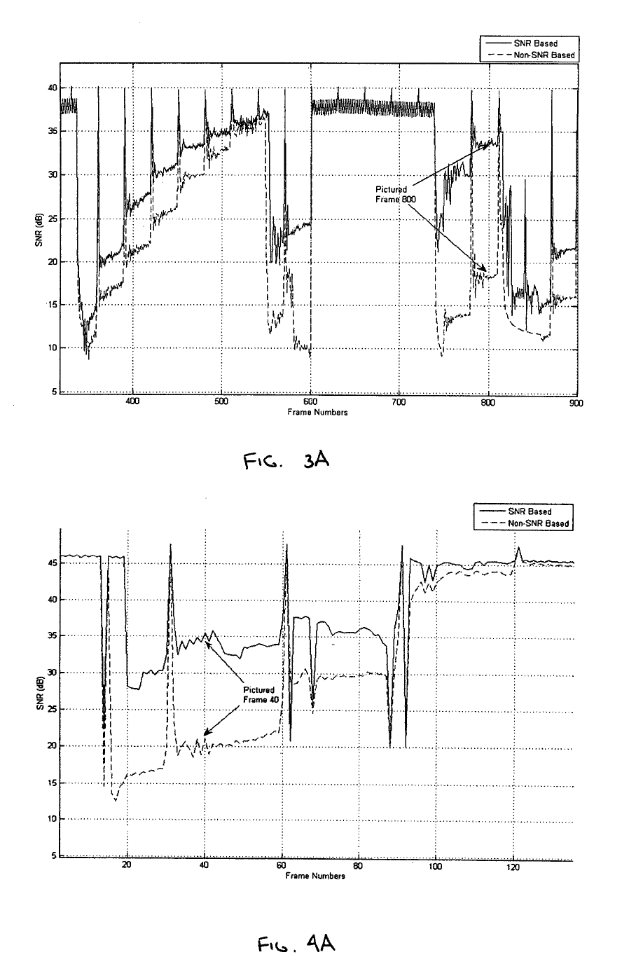

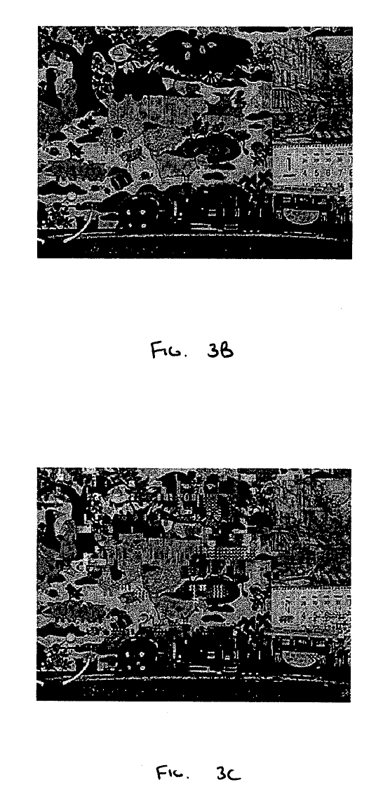

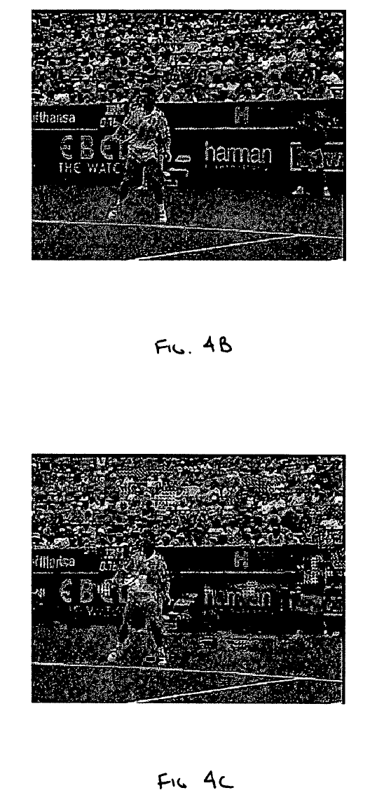

Finally it is important to verify that the improvement in error recovery performance does translate into improvement in video quality. Table I shows that the average PSNR quality over 900 frames typically improves by 1-2 db. However, in many instances for large periods in the traces the SSR is entirely in the Good Range. Thus the average PSNR does not tell the complete story. Hence for a better evaluation, FIG. 3A and FIG. 4A provide temporal snap shots for some experiments on trace 4 and 1, respectively. In the temporal snapshots it can be clearly observed that there can be multiple GOPS over which the PSNR of an SSR_aware scheme is better than an SSR_unaware by 5-15 dB. Such a big difference in video quality is perceptually visible and a typical difference in block-distortion in the two schemes is exhibited by the frame captures in FIGS. 3B and 3C as well as in FIGS. 4B and 4C. In addition to the block distortion, the motion discontinuity in an SSR_unaware scheme was also significantly higher. It should be also noted that by observing the performance of trace 1 in Table I, it can be concluded that in the transition region we can get an average PSNR improvement of 5-6 db.

In this disclosure, it has been shown that the (per packet) SSR indications are capable of providing robust channel state information. This robust channel state information is useful in improving the error recovery performance of a cross-layer FEC scheme and video throughput over cross-layer. In the good and bad SSR range the utility of the proposed scheme can be diminished but in the transition region the performance of an SSR_aware scheme consistently provides improvement. If the channel conditions are such that the SSR is in the transition region for large periods, 5-6 dB gain in terms of average PSNR quality of video can be obtained.

The above description is merely exemplary in nature and is not intended to limit the present disclosure, application, or uses.

What is claimed is:

1. A method for improving error recovery of corrupt data packets in a wireless communication system, comprising:
receiving a plurality of incoming data packets over a wireless medium at a physical layer of a receiver;
capturing an indicator of bit errors for each of the data packets at a layer of the receiver below an application layer as defined by an Open System Interconnection (OSI) model;
passing the bit error indicator for each of the data packets to the application layer of the receiver; and
performing an error recovery operation in relation to a given data packet at the application layer using the bit error indicator associated with the given data packet.

2. The method of claim 1 wherein the indicator of bits errors is reported by a communication protocol operating at a data link layer of the receiver.

3. The method of claim 1 wherein the communication protocol is further defined in accordance with the 802.11x standard.

4. The method of claim 1 wherein capturing an indicator further comprises receiving a signal to silence ratio for each data packet as reported in accordance with the 802.11b standard.

5. The method of claim 1 wherein the error recovery operation is further defined as a forward error correction scheme.

6. The method of claim 1 wherein performing an error recovery operation further comprises decoding bits of the given data packet using a low density parity check decoding scheme.

7. The method of claim 6 further comprises decoding bits of the given data packet using a log-likelihood ratio, where a bit error probability for the given data packet is derived from the passed bit error indicator.

8. The method of claim 1 further comprises determining whether each data packet contains errors prior to passing the bit error indicator and forwarding data packets without errors to the application layer without passing the bit error indicator for the data packets.

9. The method of claim 8 wherein determining whether each data packet contains errors further comprises determining whether errors are found in a header of the data packet and dropping data packets having errors in the header of the data packet.

10. The method of claim 8 wherein determining whether each data packet contains errors further comprises determining whether errors are found in a header of the data packet and passing the bit error indicator to the application layer for data packets having errors outside of the header of the data packet.

11. A method for improving error recovery of corrupt data packets in a wireless communication system, comprising:
receiving an indicator of bit errors for a given data packet at an application layer of a receiver;
translating the indicator of bit error to a bit error probability for the given data packet; and
decoding each bit in the given data packet using the bit error probability for the given data packet.

12. The method of claim 11 wherein the indicator of bits errors is a signal to silence ratio as reported by a communication protocol operating at a data link layer of the receiver.

13. The method of claim 11 wherein decoding each bit further comprises decoding each bit using a low density parity check decoding scheme.

14. The method of claim 13 further comprises decoding bits of the given data packet using a log-likelihood ratio, where a bit error probability for the given data packet is derived from the passed bit error indicator.

15. A method for improving error recovery of corrupt data packets in a wireless communication system, comprising:
receiving a plurality of incoming data packets over a wireless medium at a physical layer of a receiver, wherein the data is encoded in accordance with a forward error correction scheme;
capturing an indicator of bit errors for each of the data packets at a layer other than an application layer of the receiver;
passing the bit error indicator for each of the data packets to the application layer of the receiver; and
decoding each of the data packets at the application layer using the bit error indicator associated with the given data packet.

16. The method of claim 15 wherein the indicator of bits errors is reported by a communication protocol operating at a data link layer of the receiver.

17. The method of claim 15 wherein capturing an indicator further comprises receiving a signal to silence ratio for each data packet as reported in accordance with the 802.11b standard.

18. The method of claim 15 further comprises decoding data packets using a low density parity check decoding scheme.

19. The method of claim 18 further comprises decoding bits of a given data packet using a log-likelihood ratio, where a bit error probability for the given data packet is derived from a signal to silence ratio for each data packet as reported in accordance with the 802.11b standard.

20. The method of claim 19 further comprises deriving the bit error probability for a given data packet using an empirical relationship with the signal to silence ratio.

21. A method for improving error recovery of corrupt data packets in a wireless communication system, comprising:
receiving an incoming data packet over a wireless medium at a receiver;
determining if the data packet is error free;
forwarding the data packet to an application layer of the receiver when the data packet is error free;
determining an indicator of bit errors associated with data packet at a layer of the receiver below an application layer as defined by an Open System Interconnection (OSI) model when the data packet contains errors;
forwarding the data packet along with the bit error indicator for the data packet to the application layer; and
performing an error recovery operation in relation to the data packet at the application layer using the bit error indicator associated with the data packet.

22. The method of 21 further comprises determining if the errors occur in a header of the data packet when the data packet contains errors and dropping the data packet when the header contains errors.

23. The method of claim 21 wherein the indicator of bits errors is reported by a communication protocol operating at a data link layer of the receiver.

24. The method of claim 21 wherein determining an indicator of bit errors further comprises receiving a signal to silence ratio for the data packet as reported in accordance with the 802.11b standard.

25. The method of claim 21 wherein the error recovery operation is further defined as a forward error correction scheme.

26. The method of claim 21 wherein performing an error recovery operation further comprises decoding bits of the data packet using a low density parity check decoding scheme.

27. The method of claim 26 further comprises decoding bits of the data packet using a log-likelihood ratio, where a bit error probability for the data packet is derived from the passed bit error indicator.
